(19) United States
(12) Patent Application Publication
(10) Pub. No.: US 2026/0025975 A1
(43) Pub. Date: Jan. 22, 2026

(54) SEMICONDUCTOR DEVICE INCLUDING ISOLATION ELEMENT AND MANUFACTURING METHOD OF THE SAME

(71) Applicant: NANYA TECHNOLOGY CORPORATION, NEW TAIPEI CITY (TW)

(72) Inventor: YI-TING TSAI, NEW TAIPEI CITY (TW)

(21) Appl. No.: 18/775,201

(22) Filed: Jul. 17, 2024

(51) Int. Cl. H10B 12/00

(52) U.S. Cl. CPC H10B 12/315; H10B 12/482

(57) ABSTRACT

A semiconductor device and method for manufacturing the same are provided. The semiconductor device includes a substrate, a first spacer, a second spacer, a third spacer, a fourth spacer, a capacitor contact, an isolation element and a landing pad. The first spacer and second spacer are over the substrate and extend along the first direction. The third spacer and fourth spacer are over the substrate and extend along a second direction different from the first direction. The capacitor contact is surrounded by the first spacer, the second spacer, the third spacer, and the fourth spacer. The isolation element is disposed on the capacitor contact. The isolation element extends along the first direction. The landing pad is disposed on the isolation element and electrically connected to the capacitor contact.

### TECHNICAL FIELD

The present disclosure relates to a semiconductor device and method for manufacturing the same, and more particularly, to a semiconductor device including an isolation element and method for manufacturing the same.

### DISCUSSION OF THE BACKGROUND

With the rapid growth of the electronics industry, the development of integrated circuits (ICs) has achieved high performance and miniaturization. Technological advances in IC materials and design have produced generations of ICs where each generation has smaller and more complex circuits than the previous generation.

A Dynamic Random Access Memory (DRAM) device is a type of random access memory that stores each bit of data in a separate capacitor within an integrated circuit. Typically, a DRAM is arranged in a square array of one capacitor and transistor per cell. A vertical transistor has been developed for the 4F² DRAM cell, where F stands for the photolithographic minimum feature width or critical dimension (CD). However, recently, DRAM manufacturers face the tremendous challenge of shrinking the memory cell area as the word line spacing continues to shrink. For example, the leakage between a landing pad and a bit line has become a critical issue, which reduces the performance of a semiconductor device.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a first spacer, a second spacer, a third spacer, a fourth spacer, a capacitor contact, an isolation element and a landing pad. The first spacer and second spacer are over the substrate and extend along the first direction. The third spacer and fourth spacer are over the substrate and extend along a second direction different from the first direction. The capacitor contact is surrounded by the first spacer, the second spacer, the third spacer, and the fourth spacer. The isolation element is disposed on the capacitor contact. The isolation element extends along the first direction. The landing pad is disposed on the isolation element and electrically connected to the capacitor contact.

Another aspect of the present disclosure provides a semiconductor device. The semiconductor device includes a substrate, a first spacer, a second spacer, a capacitor contact, an isolation element and a landing pad. The first spacer and second spacer are over the substrate and extend along the first direction. The capacitor contact is disposed between the first spacer and the second spacer. The isolation element is disposed on the capacitor component. The landing pad is disposed on the capacitor contact. The landing pad includes a neck portion defined by the isolation element.

Another aspect of the present disclosure provides a method of manufacturing a semiconductor device. The method includes: providing a substrate; forming a first spacer and a second spacer over the substrate and extending along a first direction; forming a third spacer and a fourth spacer over the substrate and extending along a second direction different from the first direction, wherein the first spacer, the second spacer, the third spacer, and the fourth spacer define an opening; forming a capacitor contact within the opening; and forming an isolation element within the opening, wherein the isolation element extends along the first direction; and forming a landing pad on the isolation element and the capacitor contact.

The embodiments of the present disclosure illustrate a semiconductor device. The semiconductor device includes an isolation element over a capacitor contact. By incorporating the isolation element, the distance between a landing pad and a bit line can be increased, resulting in reduced leakage. In some embodiments, a portion of the isolation element is removed to allow a larger surface of the landing pad in contact with the capacitor contact, which reduces the resistance and enhance the performance of the semiconductor device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a top view of a semiconductor device, in accordance with some embodiments of the present disclosure.

FIG. 1B is a cross-sectional view along line A-A′ of the semiconductor device as shown in FIG. 1A, in accordance with some embodiments of the present disclosure.

FIG. 1C is a cross-sectional view along line B-B′ of the semiconductor device as shown in FIG. 1A, in accordance with some embodiments of the present disclosure.

FIG. 1D is a cross-sectional view of a semiconductor device, in accordance with some embodiments of the present disclosure.

FIG. 2 is a flowchart illustrating a method of manufacturing a semiconductor device, in accordance with some embodiments of the present disclosure.

FIG. 3 is a perspective view of an intermediate structure of a semiconductor device, in accordance with some embodiments of the present disclosure.

FIG. 3A illustrates one or more stages of an exemplary method for manufacturing a semiconductor device according to some embodiments of the present disclosure.

FIG. 3B is a cross-sectional view along line A-A′ of the semiconductor device as shown in FIG. 3A, in accordance with some embodiments of the present disclosure.

FIG. 3C is a cross-sectional view along line B-B′ of the semiconductor device as shown in FIG. 3A, in accordance with some embodiments of the present disclosure.

FIG. 4A illustrates one or more stages of an exemplary method for manufacturing a semiconductor device according to some embodiments of the present disclosure.

FIG. 4B is a cross-sectional view along line A-A′ of the semiconductor device as shown in FIG. 4A, in accordance with some embodiments of the present disclosure.

FIG. 4C is a cross-sectional view along line B-B′ of the semiconductor device as shown in FIG. 4A, in accordance with some embodiments of the present disclosure.

FIG. 5A illustrates one or more stages of an exemplary method for manufacturing a semiconductor device according to some embodiments of the present disclosure.

FIG. 5B is a cross-sectional view along line A-A′ of the semiconductor device as shown in FIG. 5A, in accordance with some embodiments of the present disclosure.

FIG. 5C is a cross-sectional view along line B-B′ of the semiconductor device as shown in FIG. 5A, in accordance with some embodiments of the present disclosure.

FIG. 6A illustrates one or more stages of an exemplary method for manufacturing a semiconductor device according to some embodiments of the present disclosure.

FIG. 6B is a cross-sectional view along line A-A′ of the semiconductor device as shown in FIG. 6A, in accordance with some embodiments of the present disclosure.

FIG. 6C is a cross-sectional view along line B-B′ of the semiconductor device as shown in FIG. 6A, in accordance with some embodiments of the present disclosure.

FIG. 7A illustrates one or more stages of an exemplary method for manufacturing a semiconductor device according to some embodiments of the present disclosure.

FIG. 7B is a cross-sectional view along line A-A′ of the semiconductor device as shown in FIG. 7A, in accordance with some embodiments of the present disclosure.

FIG. 7C is a cross-sectional view along line B-B′ of the semiconductor device as shown in FIG. 7A, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

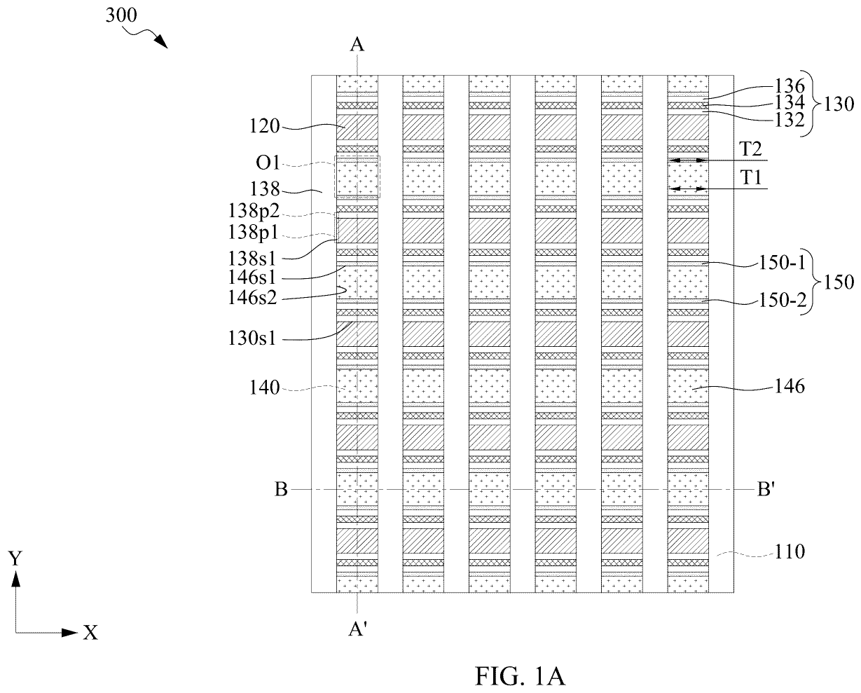

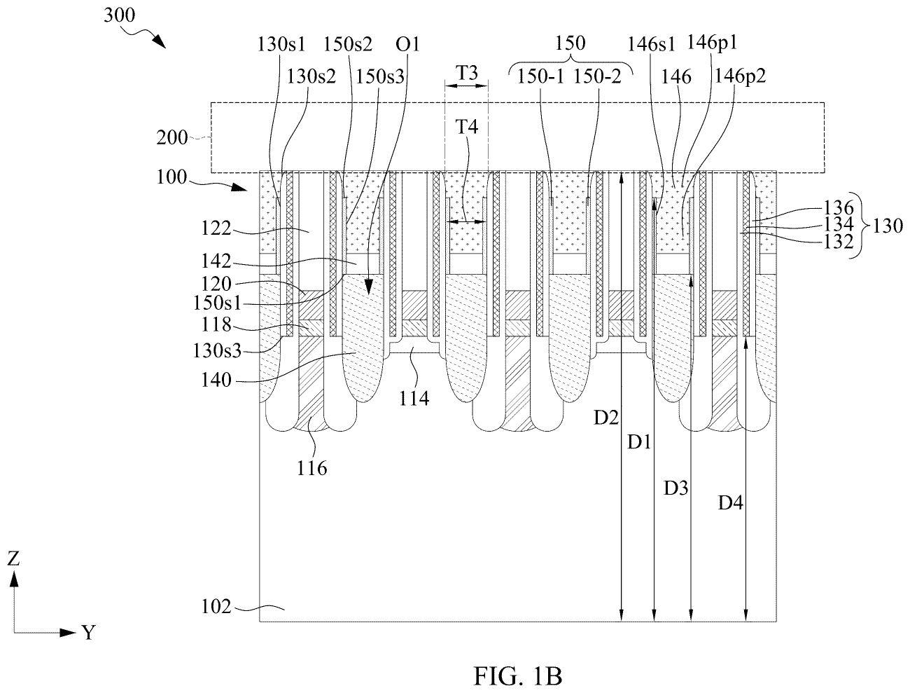

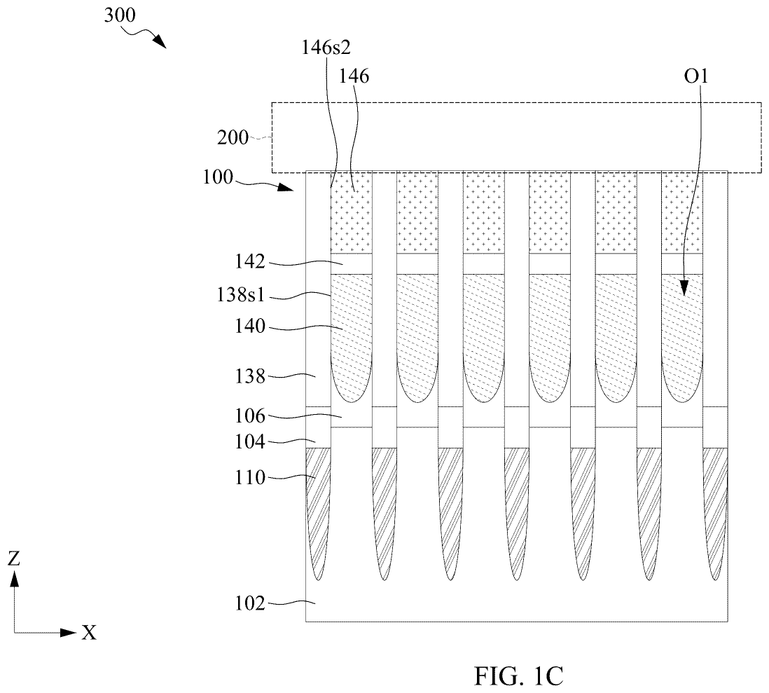

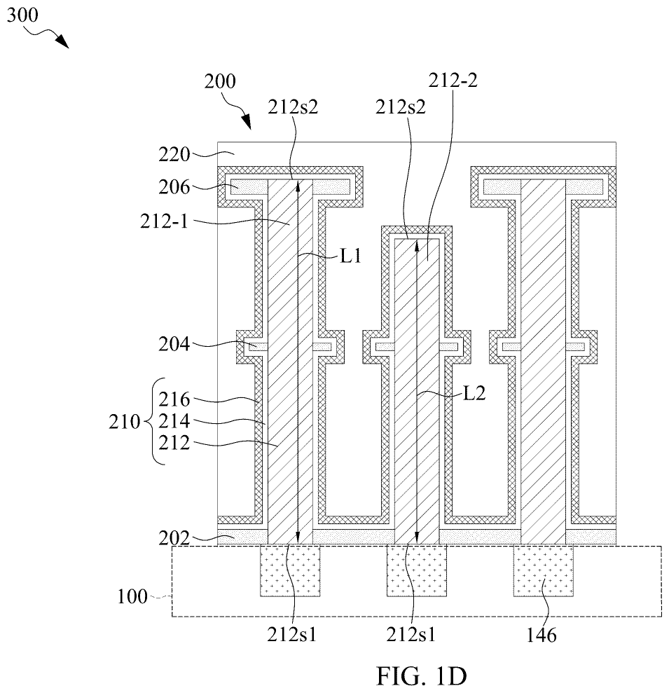

FIG. 1A, FIG. 1B, FIG. 1C, and FIG. 1D illustrate a cross-sectional view of a semiconductor device 300, in accordance with some embodiments of the present disclosure. In some embodiments, the semiconductor device 300 may include a cell region in which a memory device is formed. The memory device may include, for example, a dynamic random access memory (DRAM) device, a one-time programming (OTP) memory device, a static random access memory (SRAM) device, or other suitable memory devices. In some embodiments, a DRAM may include, for example, a transistor, a capacitor, and other components. During a read operation, a word line may be asserted, turning on the transistor. The enabled transistor allows the voltage across the capacitor to be read by a sense amplifier through a bit line. During a write operation, the data to be written may be provided on the bit line when the word line is asserted.

The semiconductor device 300 may include a carrier 100 and a device 200 disposed over the carrier 100. The carrier 100 may include a switch (e.g., transistor) configured to turn on or turn off a capacitor(s) within the device 200.

As shown in FIG. 1A, the semiconductor device 300 may include word lines 110, bit lines 120, spacers 130, spacers 140, capacitor contacts 140, pads 146, and isolation elements 150.

As shown in FIGS. 1B and 1C, the carrier 100 may include a substrate 102. The substrate 102 may be a semiconductor substrate, such as a bulk semiconductor, a semiconductor-on-insulator (SOI) substrate, or the like. The substrate 102 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, in GaInP, and GaInAsP; any other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 102 may have a multilayered structure, or the substrate 102 may include a multilayered compound semiconductor structure.

In some embodiments, the carrier 100 may include a plurality of active areas. The active area may function as, for example, a channel for electrical connection.

In some embodiments, the carrier 100 may include isolation structures (not shown). In some embodiments, the plurality of active areas may be separated by the isolation structures. In some embodiments, the isolation structure may be embedded in the substrate 102. In some embodiments, the isolation structure may include, for example, silicon oxide (SiO₂), silicon nitride (Si₃N₄), silicon oxynitride (N₂OSi₂), silicon nitride oxide (N₂OSi₂), or other suitable materials. In some embodiments, a portion of the substrate 102 may be removed to form trenches, and a dielectric material(s) is filled into the trenches to form the isolation structures. In some embodiments, the isolation structure may include a shallow trench isolation (STI).

The carrier 100 may include dielectric layers 104. In some embodiments, the dielectric layer 104 may be disposed within the substrate 102. The dielectric layer 104 may include, for example, silicon oxide (SiO₂), silicon nitride (Si₃N₄), silicon oxynitride (N₂OSi₂), silicon nitride oxide (N₂OSi₂), a high-k material or combinations thereof.

Each of the word lines 110 may extend along the Y direction. The word line 110 may be disposed within the substrate 102. The word line 110 may be embedded within the substrate 102. The word line 110 may be disposed on or under the dielectric layer 104. The word line 110 may include a gate dielectric layer and a gate electrode (not shown). The gate dielectric layer may include silicon oxide or other suitable materials. The gate electrode may include a conductive material(s), such as titanium nitride, tungsten, polysilicon, or other suitable materials.

In some embodiments, the carrier 100 may include isolation layers 106. The isolation layer 106 may be disposed on or over the substrate 102. The isolation layer 106 may separate the capacitor contact 140 from the substrate 102. The isolation layer 106 may include, for example, silicon oxide (SiO₂), silicon nitride (Si₃N₄), silicon oxynitride (N₂OSi₂), silicon nitride oxide (N₂OSi₂), or other suitable materials.

In some embodiments, the carrier 100 may include dielectric layers 114. The dielectric layer 114 may be disposed on the substrate 102. The dielectric layer 114 may be configured to separate a portion of the bit lines 120 from the substrate 102. In some embodiments, the dielectric layer 114 may include, for example, silicon oxide (SiO₂), silicon nitride (Si₃N₄), silicon oxynitride (N₂OSi₂), silicon nitride oxide (N₂OSi₂), a high-k material or combinations thereof. Examples of the high-k material include a dielectric material having a dielectric constant exceeding that of silicon dioxide (SiO₂), or a dielectric material having a dielectric constant higher than about 3.9. In some embodiments, the dielectric layer 114 may include at least one metallic element, such as hafnium oxide (HfO₂), silicon doped hafnium oxide (HSO), lanthanum oxide (La₂O₃), lanthanum aluminum oxide (LaAlO₃), zirconium orthosilicate (ZrSiO₄), aluminum oxide (Al₂O₃) or combinations thereof.

In some embodiments, the carrier 100 may include bit line contacts 116. In some embodiments, the bit line contact 116 may be disposed on the active area of the 100. The bit line contact 116 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability.

In some embodiments, the carrier 100 may include bit line stacks 118. In some embodiments, the bit line stack 118 may include a multilayered structure. In some embodiments, a portion of the bit line stacks 118 may be disposed on the bit line contact 116. A portion of the bit line stacks 118 may be spaced apart from the substrate 102 by the dielectric layer 114. In some embodiments, a portion of the bit line stacks 118 may be in contact with the bit line contact 116. In some embodiments, a portion of the bit line stacks 118 may be electrically connected to the bit line contact 116. In some embodiments, a portion of the bit line stacks 118 may be disposed on the dielectric layer 114. In some embodiments, a portion of the bit line stacks 118 may be in contact with the dielectric layer 114. The bit line stack 118 may include titanium (Ti), tantalum (Ta), titanium nitride (TiN), copper (Cu), tantalum nitride (TaN), manganese nitride (MnN) or a combination thereof.

As shown in FIG. 1A, each of the bit lines 120 may extend along the X direction. As shown in FIG. 1B, each of the bit lines 120 may be disposed on the bit line stack 118. In some embodiments, a portion of the bit lines 120 may be disposed on the bit line contacts 116. In some embodiments, a portion of the bit lines 120 may be electrically connected to the bit line contacts 116. In some embodiments, a portion of the bit line 120 may be disposed on the dielectric layer 114. The bit line 120 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys thereof, or combinations thereof.

In some embodiments, the carrier 100 may include dielectric layers 122. In some embodiments, each of the dielectric layers 122 may be disposed on the bit lines 120. In some embodiments, the dielectric layer 122 may include, for example, silicon oxide, silicon nitride, silicon oxynitride, silicon nitride oxide, a high-k material or combinations thereof.

As shown in FIG. 1A, each of the spacers 130 may extend along the X direction. The spacers 130 may be disposed on opposite sides (or sidewalls) of the bit line 120. The spacer 130 may include a multilayer structure. For example, the spacer 130 may have dielectric layers 132, 134, and 136.

In some embodiments, the dielectric layer 132 may be formed on the sidewalls of the bit line contact 116, the bit line stack 118, the bit line 120, and the dielectric layer 122. In some embodiments, a portion of the dielectric layer 132 may be embedded in the substrate 102. In some embodiments, the dielectric layer 132 may include, for example, silicon nitride, silicon oxide, silicon oxynitride, silicon nitride oxide, a high-k material or combinations thereof.

In some embodiments, the dielectric layer 134 may be spaced apart from the bit line 120 by the dielectric layer 132. The dielectric layer 134 may be disposed between the dielectric layers 132 and 136. In some embodiments, the dielectric layer 134 may include, for example, silicon oxide, silicon nitride, silicon oxynitride, silicon nitride oxide, a high-k material or combinations thereof. The dielectric layer 134 may include a material different from that of the dielectric layer 132.

In some embodiments, the dielectric layer 136 may be spaced apart from the dielectric layer 132 by the dielectric layer 134. In some embodiments, the dielectric layer 136 may include, for example, silicon nitride, silicon oxide, silicon oxynitride, silicon nitride oxide, a high-k material or combinations thereof. The dielectric layer 136 may include a material different from that of the dielectric layer 132. For example, the dielectric layers 132 and 136 may include silicon nitride, and the dielectric layer 134 may include silicon oxide. In some embodiments, the dielectric layer 134 may be replaced by an air gap.

In some embodiments, the dielectric layer 136 may have a rounding corner so that the top surface of the dielectric layer 136 may be tapered.

As shown in FIG. 1A, each of the spacers 138 may extend along the Y direction in some embodiments. As shown in FIG. 1C, the spacer 138 may be disposed on or directly over the word line 110. The spacer 138 may cover a portion of the spacers 130. In some embodiments, the spacer 138 may include, for example, silicon oxide, silicon nitride, silicon oxynitride, silicon nitride oxide, a high-k material or combinations thereof.

In some embodiments, the spacers 130 and spacers 138 may define openings O1 from a top view. The opening O1 may have a rectangle profile, a circular profile, an elliptical profile, an oval profile, or other suitable profiles.

In some embodiments, the capacitor contacts 140 may be disposed within the openings O1. In some embodiments, the capacitor contact 140 may be formed between two bit lines 120. In some embodiments, the capacitor contact 140 may be formed between the spacer 130. The capacitor contact 140 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, combinations thereof or any metallic material.

In some embodiments, the carrier 100 may include conductive stack structures 142. In some embodiments, the conductive stack structure 142 may be disposed within the opening O1. In some embodiments, the conductive stack structure 142 may be disposed on or over the capacitor contact 140. The conductive stack structure 142 may include a multilayered structure. The conductive stack structure 142 may be disposed between the spacers 130 (or spacers 138). In some embodiments, the conductive stack structure 142 may include metal silicide, such as, cobalt silicide (CoSi) or other suitable materials.

In some embodiments, the pads (or landing pads) 146 may be disposed within the openings O1. Each of the pads 146 may be configured to electrically connect a capacitor component (shown in FIG. 1D). In some embodiments, the pad 146 may be formed between the spacers 130. In some embodiments, the pad 146 may be formed between the spacers 138. In some embodiments, the pad 146 may cover a top surface of the conductive stack structure 142. In some embodiments, the pad 146 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys thereof, or combinations thereof.

In some embodiments, the carrier 100 may include isolation elements 150. In some embodiments, the isolation elements 150 may be disposed within the openings O1. In some embodiments, each of the openings O1 may be configured to accommodate two separated isolation elements 150-1 and 150-2. In some embodiments, each of the isolation elements 150 (e.g., isolation elements 150-1 and 150-2) may extend along the X direction as shown in FIG. 1A. In some embodiments, the isolation element 150 may disposed on a surface 130s1 (or a lateral surface) of the spacer 130. For example, the isolation element 150 may be disposed on a sidewall of the dielectric layer 136. The isolation element 150 may continuously extend between the spacers 138. In some embodiments, the isolation element 150 may include silicon nitride, silicon oxynitride, or a combination thereof. In some embodiments, the material of the isolation element 150 may be the same as or similar to that of the spacer 130.

As shown in FIG. 1, the spacer 138 may have a surface (or side) 138s1 facing the pad 146. In some embodiments, a portion of the surface 138s1 may be exposed by the 50 from a top view. In some embodiments, a portion 138p1 of the surface 138s1 of the spacer 138 may be exposed by the isolation element 150 from a top view. In some embodiments, a portion 138p2 of the surface 138s1 of the spacer 138 may be covered by the isolation element 150 from a top view. The pad 146 may have a length T1 along the X direction. The isolation element 150 may have a length T2 along the X direction. In some embodiments, the length T1 may be substantially equal to the length T2.

As shown in FIG. 1B, the isolation element 150 may be disposed on or over the capacitor contact 140. In some embodiments, the isolation element 150-1 and isolation element 150-2 may be disposed on two sidewalls (or lateral surface) of the portion 146p2 of the pad 146. In some embodiments, the isolation element 150-1 and isolation element 150-2 may be disposed on two sidewalls (or lateral surfaces) of the conductive stack structure 142. In some embodiments, the isolation element 150-1 may be spaced apart from the isolation element 150-2 by the conductive stack structure 142. In some embodiments, the isolation element 150-1 may be spaced apart from the isolation element 150-2 by the portion 146p2 of the pad 146.

The isolation element 150 may have a surface 150sl (or a lower surface) abutting the capacitor contact 140, a surface 150s2 (or an upper surface) opposite to the surface 150s1, and a surface 150s3 (or a lateral surface) extending between the surface 150sl and the surface 150s2. In some embodiments, the pad 146 may cover or be in contact with the surface 150s2 of the isolation element 150. In some embodiments, the portion 146p1 of the pad 146 may cover the surface 150s2 of the isolation element 150. In some embodiments, the pad 146 may cover or be in contact the surface 150s3. In some embodiments, the portion 146p2 of the pad 146 may cover or be in contact the surface 150s3. In some embodiments, the conductive stack structure 142 may cover or be in contact the surface 150s3. The portion 146p1 of the pad 146 may have a length T3 along the Y direction. The portion 146p2 of the pad 146 may have a length T3 along the Y direction. In some embodiments, the length T4 may be less than the length T3.

As shown in FIG. 1A, and FIG. 1B, a surface 146s1 (or lateral surface) of the pad 146 may be in contact with the isolation element 150. As shown in FIG. 1A, and FIG. 1C, a surface 146s2 (or lateral surface) of the pad 146 may be in contact with the spacer 138. The surface 146s1, extending along the X direction, may abut the surface 146s2, extending along the Y direction. As shown in FIG. 1B, the pad 146 may have a portion (or an upper portion) 146p1 over the isolation elements 150 and a portion (or a lower portion or a neck portion) 146p2 surrounded by the isolation elements 150 (e.g., isolation elements 150-1 and 150-2).

As shown in FIG. 1B, distance D1 between the surface 150s2 of the isolation element 150 and the substrate 102 may be different from a distance D2 between a surface 130s2 (or upper surface) of the spacer 130 and the lower surface (or backside surface) of the substrate 102. For example, the distance D1 may be less than the distance between the upper surface of the dielectric layer 136 and the lower surface (or backside surface) of the substrate 102. In some embodiments, the distance D2 may be greater than the distance D1. In some embodiments, a distance D3 between the surface 150s1 of the isolation element 150 and the lower surface (or backside surface) of the substrate 102 may be different from a distance D4 between the surface 130s3 (or lower surface) of the spacer 130 and the lower surface (or backside surface) of the substrate 102. In some embodiments, the distance D3 may be greater than the distance D4. For example, the distance D3 may be greater than the distance between the lower surface of the dielectric layer 136 and the lower surface (or backside surface) of the substrate 102. In some embodiments, the surface 130s2 of the spacer 130 may be misaligned or noncoplanar with the surface 150s2 of the isolation element 150. For example, the upper surface of the dielectric layer 136 and the substrate 102 may be misaligned or noncoplanar with the surface 150s2 of the isolation element 150.

In this embodiment, the isolation element 150 may be configured to increase the distance (e.g., a distance along the Y direction) between the pad 146 and the bit line 120, thereby preventing leakage between the pad 146 and the bit line 120. Further, the isolation element 150 exposes a portion of the spacer 138. For example, the portion 138p1 of the surface 138s1 of the space 138 may be exposed by the isolation element 150. As a result, the interface between the pad 146 and the capacitor contact 140 may be greater than a comparative example that the isolation element 150 is formed on the portion 138p1 of the surface 138s1 of the space 138, thereby reducing the resistance.

FIG. 1D illustrates the device 200 in detail according to some embodiments of the present disclosure. In some embodiments, the semiconductor device 300 may include a device 200. The device 200 may be disposed on or over the pads 146. The device 200 may include a capacitor component electrically connected to the pads 146. The transistors shown in FIG. 1 may be configured to switch on or off the capacitor component within the device 200.

The device 200 may be disposed over the carrier 100 to cover the pad 146. In some embodiments, the device 200 may include a supporting layer 202, a supporting layer 204, and a supporting layer 206 which are located at different elevations and configured to support a capacitor component 210.

In some embodiments, the supporting layer 202 (or a lower supporting layer) may be disposed on or over the passivation layer 148. In some embodiments, the supporting layer 202 may cover a portion of the pad 146. In some embodiments, the supporting layer 202 may be in contact with the pad 146. In some embodiments, the supporting layer 202 may be configured to support the capacitor component 210. The supporting layer 202 may be utilized to define the patterns of the capacitor component 210. In some embodiments, the supporting layer 202 may include silicon nitride, silicon oxide, silicon oxynitride, silicon nitride oxide, or other suitable materials.

In some embodiments, the supporting layer 204 (or a middle supporting layer) may be disposed on or over the supporting layer 202. In some embodiments, the supporting layer 204 may be spaced apart from the supporting layer 202. In some embodiments, the supporting layer 204 may be configured to support the capacitor component 210. The supporting layer 204 may be utilized to define the patterns of the capacitor component 210. In some embodiments, the supporting layer 204 may include silicon nitride, silicon oxide, silicon oxynitride, silicon nitride oxide, or other suitable materials.

In some embodiments, the supporting layer 206 (or an upper supporting layer) may be disposed on or over the supporting layer 204. In some embodiments, the supporting layer 206 may be spaced apart from the supporting layer 204. In some embodiments, the supporting layer 206 may be configured to support the capacitor component 210. The supporting layer 206 may be utilized to define the patterns of the capacitor component 210. In some embodiments, the supporting layer 206 may include silicon nitride, silicon oxide, silicon oxynitride, silicon nitride oxide, or other suitable materials.

The capacitor component 210 may be disposed on or over the carrier 100. In some embodiments, the capacitor component 210 may be electrically connected to the pad 146. In some embodiments, the capacitor component 210 may be supported by and in contact with the supporting layer 202, supporting layer 204, and supporting layer 206. In some embodiments, the capacitor component 210 may include a lower electrode 212, a capacitor dielectric 214, and an upper electrode 216.

In some embodiments, the lower electrode 212 (or first electrode) may be disposed on the carrier 100. In some embodiments, the lower electrode 212 may be disposed on and electrically connected to the pad 146. In some embodiments, the lower electrode 212 may be disposed within the opening defined by the supporting layer 202, supporting layer 204, and supporting layer 206. In some embodiments, the lower electrode 212 may be disposed on or in contact with the lateral surface of the supporting layer 202. In some embodiments, the lower electrode 212 may be disposed on or in contact with the lateral surface of the supporting layer 204. In some embodiments, the lower electrode 212 may be disposed on or in contact with the lateral surface of the supporting layer 206. The lower electrode 212 may include conductive material(s), conductive metal nitride (e.g., titanium nitride, tantalum nitride, tungsten nitride, or the like), metal (e.g., copper, tungsten, ruthenium, iridium, nickel, osmium, rhodium, aluminum, molybdenum, cobalt, or the like), and conductive metal oxide (e.g., iridium oxide or the like).

The lower electrode 212 may have a surface 212s1 (or a lower surface) abutting the carrier 100 and a surface 212s2 (or an upper surface) opposite to the surface 210s1. In some embodiments, the thickness L1 (or length or depth) of the lower electrode 212-1 may be different from the thickness L2 (or length or depth) of the lower electrode 212-2.

The capacitor dielectric 214 may be conformally disposed on the lower electrode 212. In some embodiments, the capacitor dielectric 214 may be disposed on or in contact with the upper surface of the supporting layer 202. In some embodiments, the capacitor dielectric 214 may be disposed on or in contact with the upper surfaces of the supporting layer 204 and supporting layer 206. In some embodiments, the capacitor dielectric 214 may be disposed on or in contact with the lower surfaces of the supporting layer 204 and supporting layer 206. In some embodiments, the capacitor dielectric 214 may be disposed on or in contact with the lateral surfaces of the supporting layer 204 and supporting layer 206. The capacitor dielectric 214 may include silicon oxide, tungsten oxide, copper oxide, aluminum oxide, hafnium oxide, or the like.

In some embodiments, the upper electrode 216 (or second electrode) may be disposed on the capacitor dielectric 214. The upper electrode 216 may be spaced apart from the lower electrode 212 by the capacitor dielectric 214. The upper electrode 216 may include conductive material(s), conductive metal nitride (e.g., titanium nitride, tantalum nitride, tungsten nitride, or the like), metal (e.g., copper, tungsten, ruthenium, iridium, nickel, osmium, rhodium, aluminum, molybdenum, cobalt, or the like), and conductive metal oxide (e.g., iridium oxide or the like). In some embodiments, each of the supporting layer 202, supporting layer 204, and supporting layer 206 may define a ring profile, from a top view, to accommodate the capacitor component 210.

In some embodiments, the device 200 further includes a grounding electrode 220. In some embodiments, the grounding electrode 220 may be electrically connected to ground. In some embodiments, the grounding electrode 220 may be electrically connected to the capacitor component 210. In some embodiments, the grounding electrode 220 may be electrically connected to and in contact with the upper electrode 216. In some embodiments, the grounding electrode 220 may include doped polysilicon or other suitable materials.

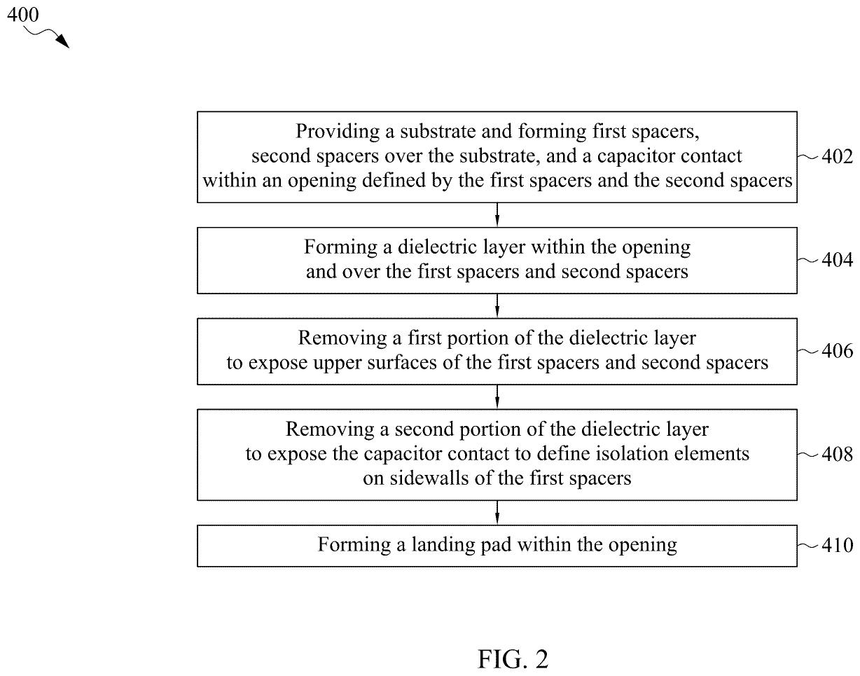

FIG. 2 is a flowchart illustrating a method 400 of manufacturing a semiconductor device, in accordance with some embodiments of the present disclosure.

The method 400 may begin with an operation 402 in which a substrate is provided. The substrate has active regions defined by isolation structures (STI structures). Word lines are formed within the substrate. Bit lines are formed over the substrate. First spacers are formed on the opposite sides of the bit lines. Second spacers are formed directly over the word lines. The bit line extends along a first direction. The first spacer extends along the first direction. The word line extends along a second direction substantially orthogonal to the first direction. The second spacer extends along the second direction. The first spacers and the second spacers define openings. Capacitor contacts are formed within the openings.

The method 400 may continue with an operation 404 in which a dielectric layer is conformally formed on or over the capacitor contact, the first spacers, and the second spacers. The dielectric layer is conformally formed within the openings defined by the first spacers and the second spacers.

The method 400 may continue with an operation 406 in which a first portion, over the upper surfaces of the first spacers and the upper surfaces of the second spacers, of the dielectric layer is removed. The remaining portion of the dielectric layer is within the openings. The upper surfaces of the first spacers and the second spacers are exposed.

The method 400 may continue with an operation 408 in which a second portion of the dielectric layer is removed to expose the upper surface of the capacitor contact and to expose the lateral surfaces of the second spacers. The remaining dielectric layer is formed on sidewalls of the first spacers and extends along the first direction. As a result, isolation elements are produced.

The method 400 may continue with an operation 410 in which landing pads are formed within the opening. The landing pads are formed on the isolation elements and on the capacitor contacts. The landing pad is spaced apart from the bit line by the first spacer and the isolation element.

The method 400 is merely an example, and is not intended to limit the present disclosure beyond what is explicitly recited in the claims. Additional operations can be provided before, during, or after each operations of the method 400, and some operations described can be replaced, eliminated, or reordered for additional embodiments of the method. In some embodiments, the method 400 can include further operations not depicted in FIG. 2. In some embodiments, the method 400 can include one or more operations depicted in FIG. 2.

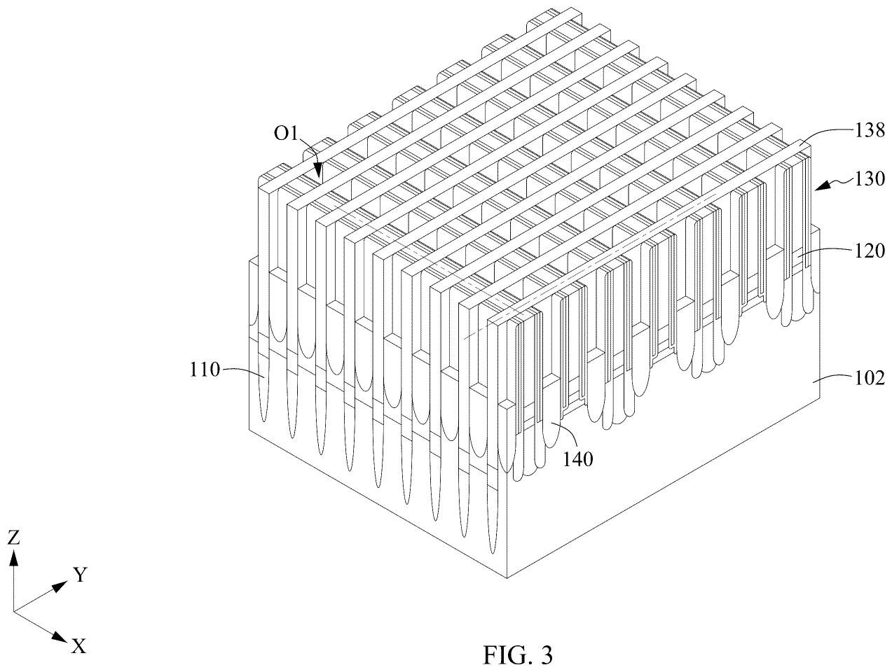

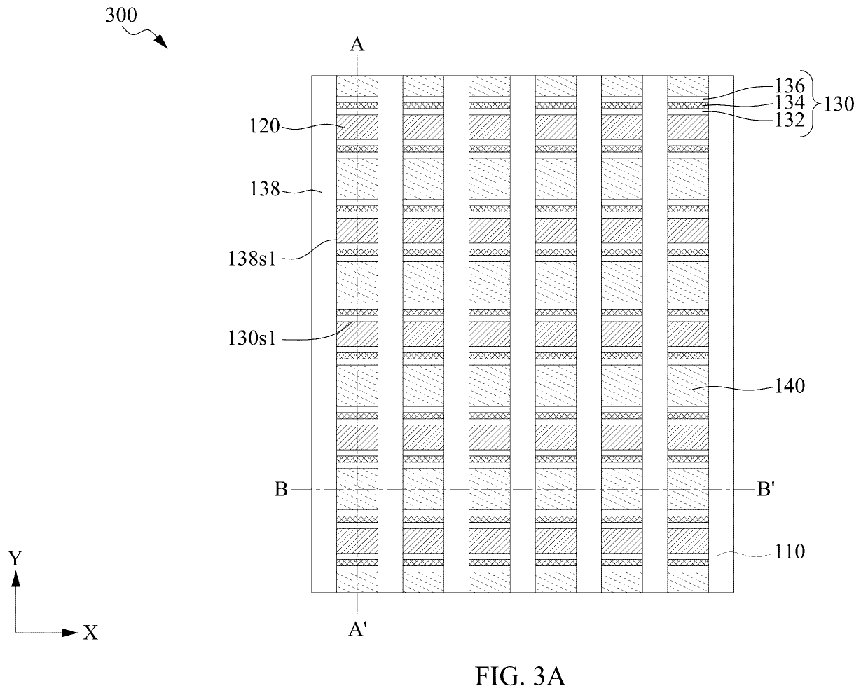

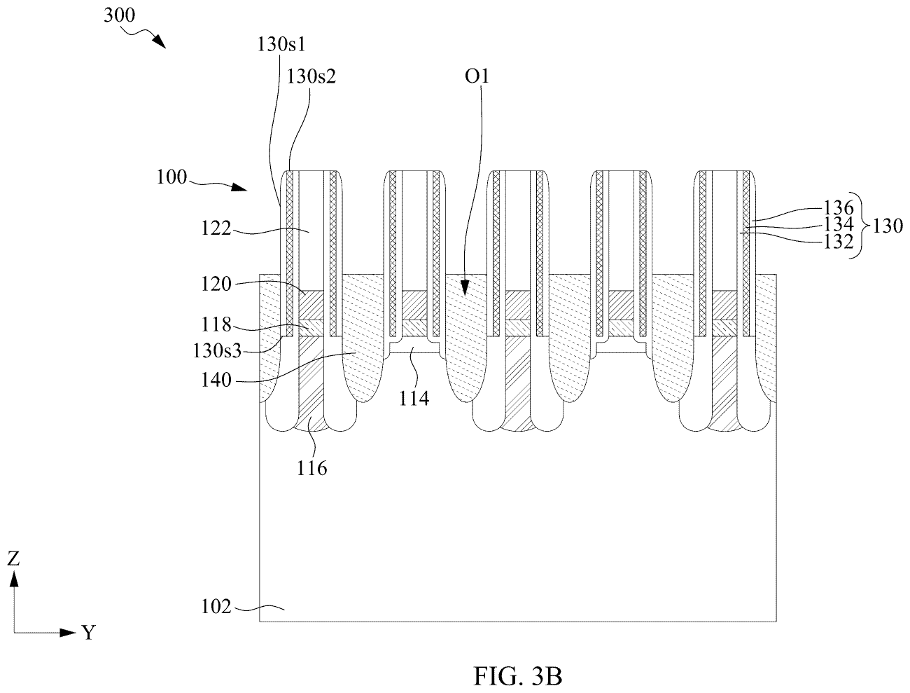

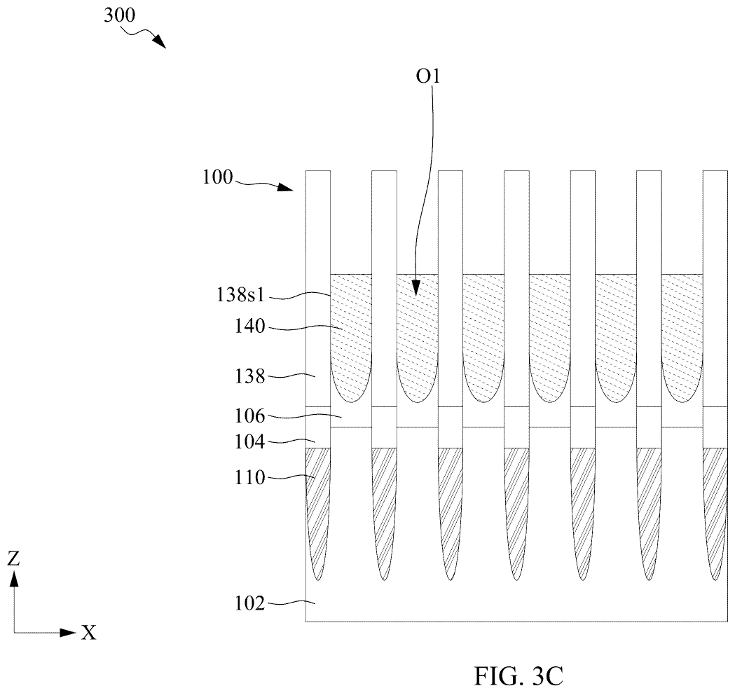

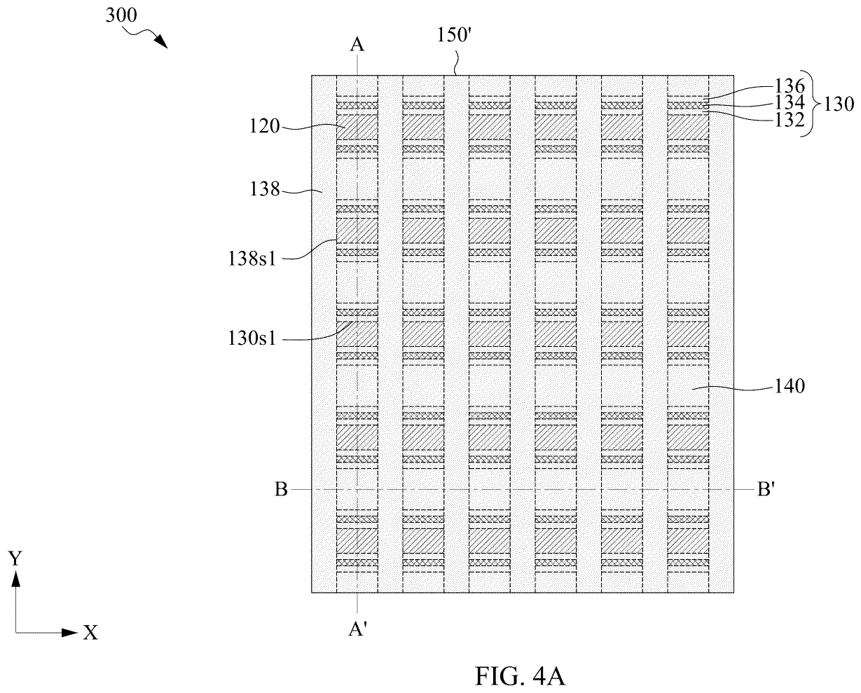

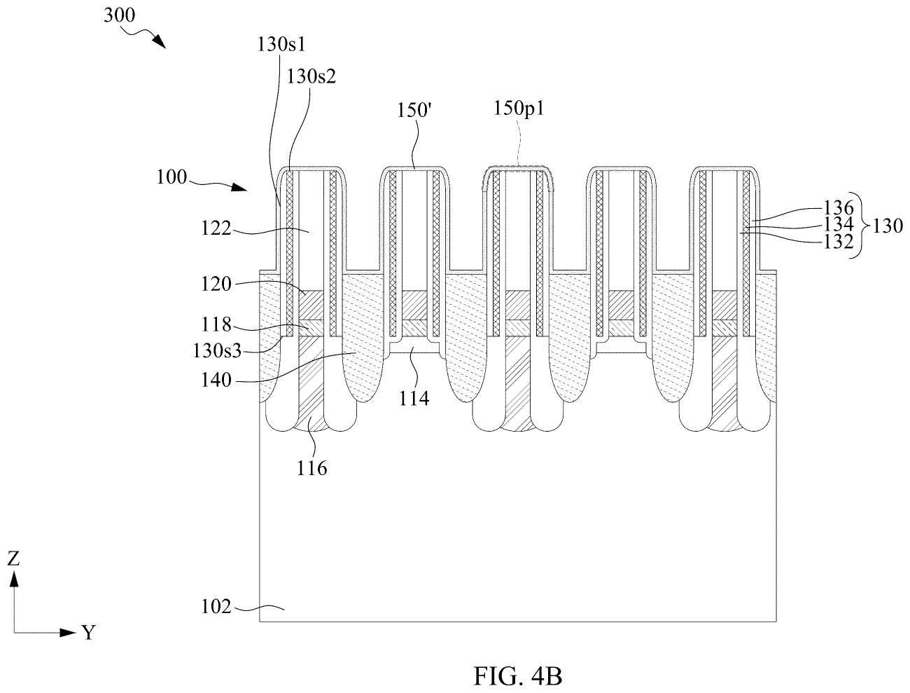

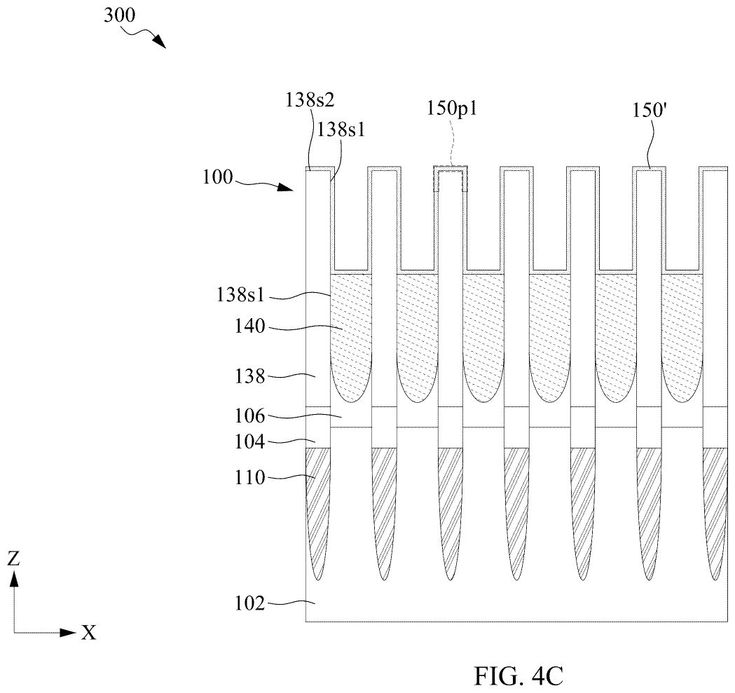

FIG. 3 is a perspective view of an intermediate structure of a semiconductor device. FIG. 3A is a top view of FIG. 3, FIG. 3B and FIG. 3C are cross-sectional views of FIG. 3A. FIGS. 4A to 4C, 5A to 5C, 6A to 6C, and 7A to 7C illustrate structures followed by the stage as shown in FIGS. 3A to 3C, respectively

Referring to FIGS. 3, 3A, 3B, and 3C, a substrate 102 is provided. In some embodiments, the substrate 102 may include a plurality of active areas. Dielectric layers 114 may be formed on the substrate 102. In some embodiments, the dielectric layer 114 may be formed by chemical vapor deposition (CVD), atomic layer deposition (ALD), physical vapor deposition (PVD), low-pressure chemical vapor deposition (LPCVD), flowable chemical vapor deposition (FCVD), or other suitable processes.

Word lines 110 may be formed within the substrate 102. In some embodiments, a plurality of trenches may be formed, and a gate dielectric material and a gate electrode material may be formed within the trenches to produce the word line 110. Each of the gate dielectric material and the gate electrode material may be formed by, for example, CVD, ALD, FCVD, PVD, LPCVD, or other suitable processes.

In some embodiments, a portion of the substrate 102 may be removed to form an opening. In some embodiments, a conductive material(s) may fill the trench to produce the bit line contacts 116. In some embodiments, the bit line contact 116 may be formed by CVD, ALD, PVD, FCVD, LPCVD, or other suitable processes. Further, a chemical polishing process may be performed to planarize the top surfaces of the bit line contact 116 and the dielectric layer 114.

In some embodiments, bit line stacks 118, bit lines 120, and dielectric layers 122 may be formed over the substrate 102 and the dielectric layer 114. The bit line stack 118, the bit line 120, and the dielectric layer 122 may be patterned to extend along the X direction. Each of the bit line stack 118, the bit line 120, and the dielectric layer 122 may be formed by CVD, ALD, PVD, FCVD, LPCVD, or other suitable processes.

A portion of the substrate 102 may be removed. A portion of the dielectric layer 114 may be removed. Spacers 130 may be formed on sidewalls (or lateral surfaces) of the bit line stack 118, the bit line 120, and the dielectric layer 122 and over the substrate 102 and the dielectric layer 114. Each of the dielectric layers 132, 134, and 136 may be formed by CVD, ALD, PVD, FCVD, LPCVD, or other suitable processes.

A dielectric material(s) may be formed on the dielectric layer 122 and on the dielectric layer 104 and then patterned to form the spacers 138 extending along the Y direction. The spacers 138 may cover the spacers 130. The spacer 138 may be formed by, for example, CVD, ALD, PVD, FCVD, LPCVD, or other suitable processes.

In some embodiments, the spacers 138 and the spacers 130 may define openings O1. Capacitor contacts 140 may be formed within the openings O1. The capacitor contact 140 may be formed by, for example, CVD, ALD, PVD, FCVD, LPCVD, or other suitable processes.

Referring to FIGS. 4A, 4B, and 4C, a dielectric layer 150′ may be conformally formed on the surface 130s1 of the spacer 130, on the surface 130s2 of the spacer 130, on the upper surface of the capacitor contact 140, on the surface 138s1 of the spacer 138, and on a surface 138s2 (or an upper surface) of the spacer 138. The dielectric layer 150′ may be formed by, for example, ALD, CVD, PVD, FCVD, LPCVD, or other suitable processes.

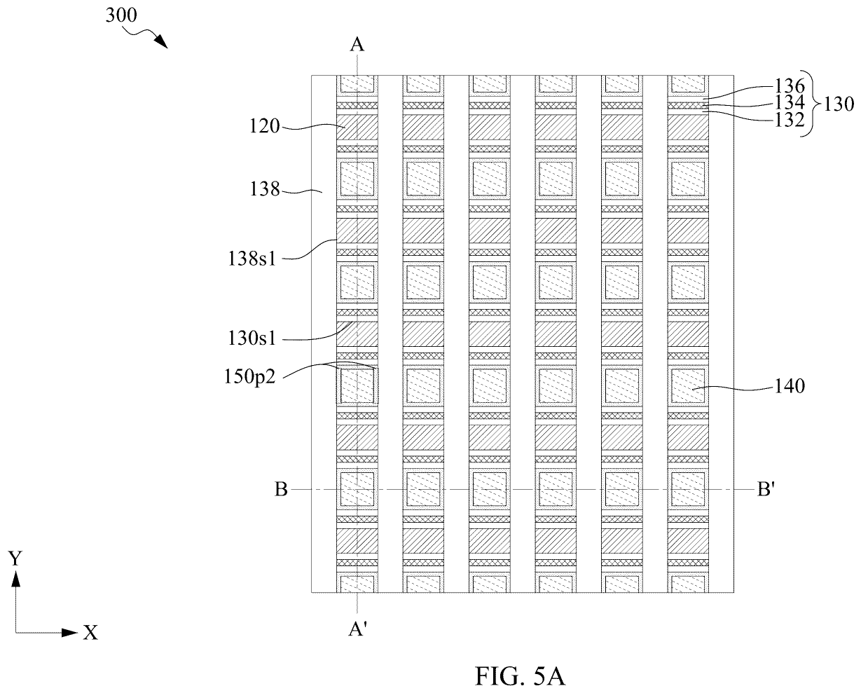

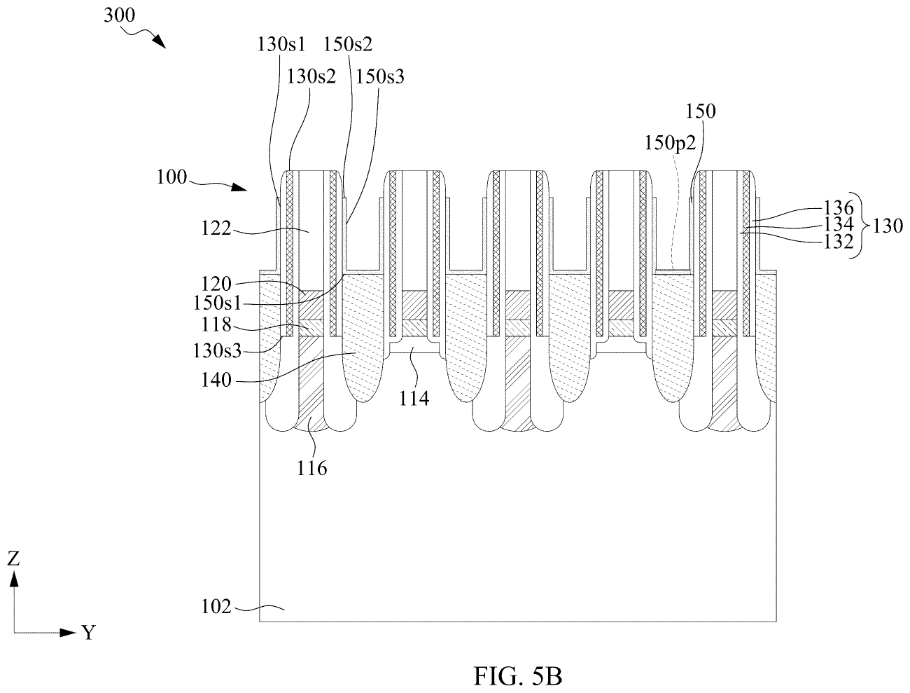

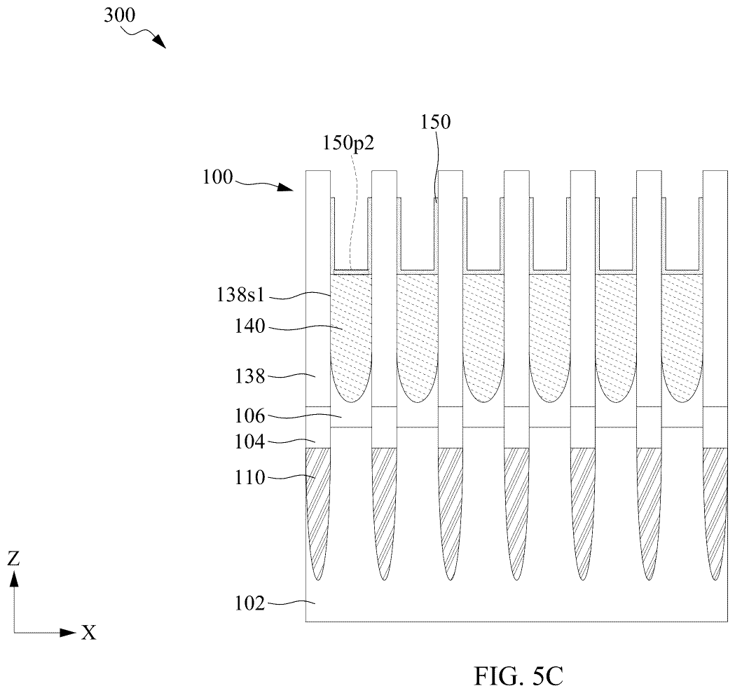

Referring to FIGS. 5A, 5B, and 5C, a portion 150p1, as shown in FIGS. 4B and 4C may be removed. The portion 150p1 may be located over the surface 130s2 of the spacer 130. The portion 150p1 may partially cover the surface 130sl of the spacer 130. The portion 150p1 may be located over the surface 138s2 of the spacer 138. The portion 150p1 may partially cover the surface 138s1 of the spacer 138. As a result, the surface 150s2 of the isolation element 150 may be located at an elevation (or level), with respect to the substrate 102, lower than that of the surface 130s2 of the spacer 130. The portion 150p1 of the isolation element 150 may be removed by an etching technique, such as a dry etching technique or other suitable techniques.

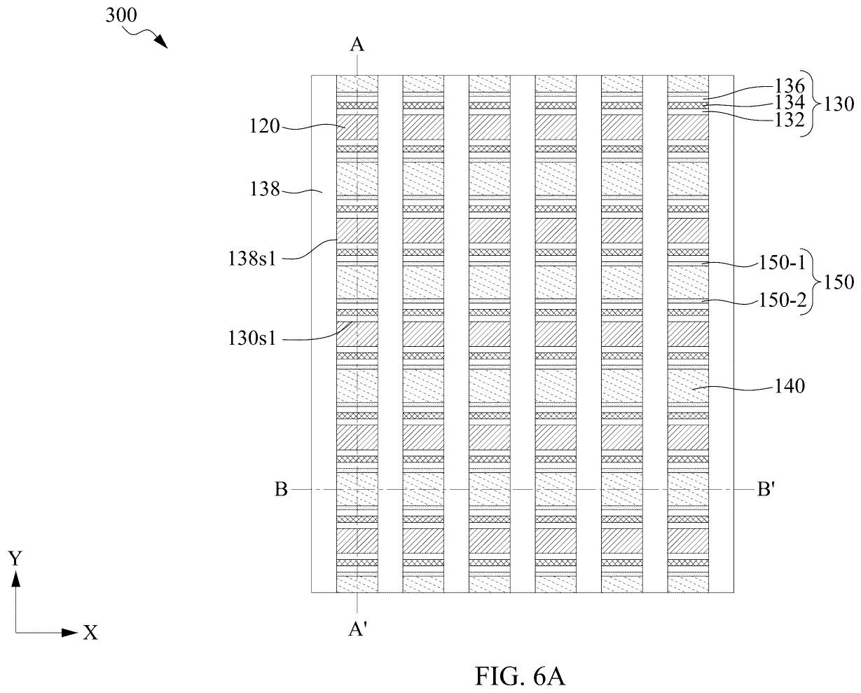

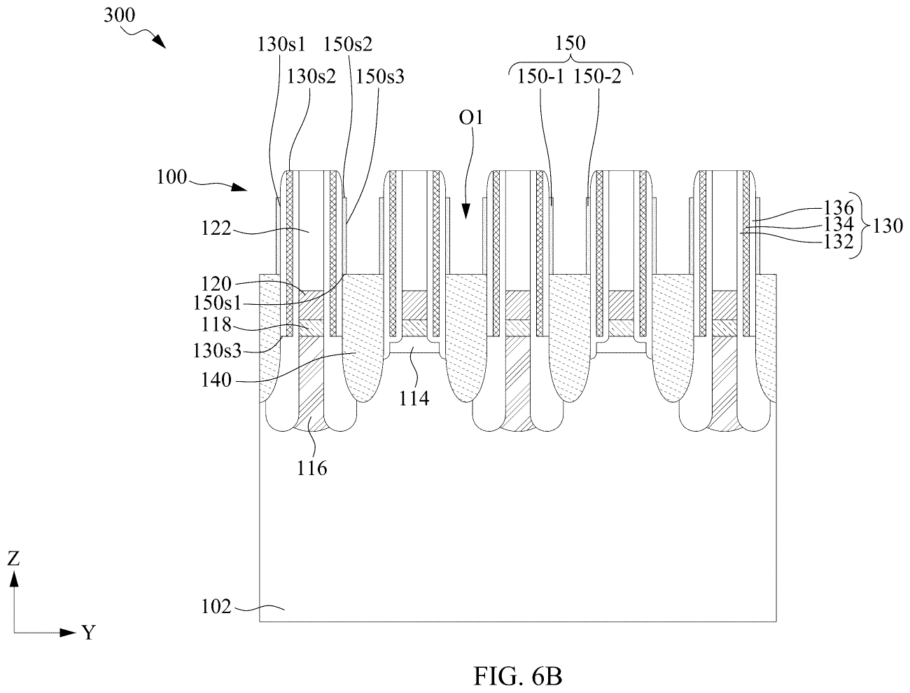

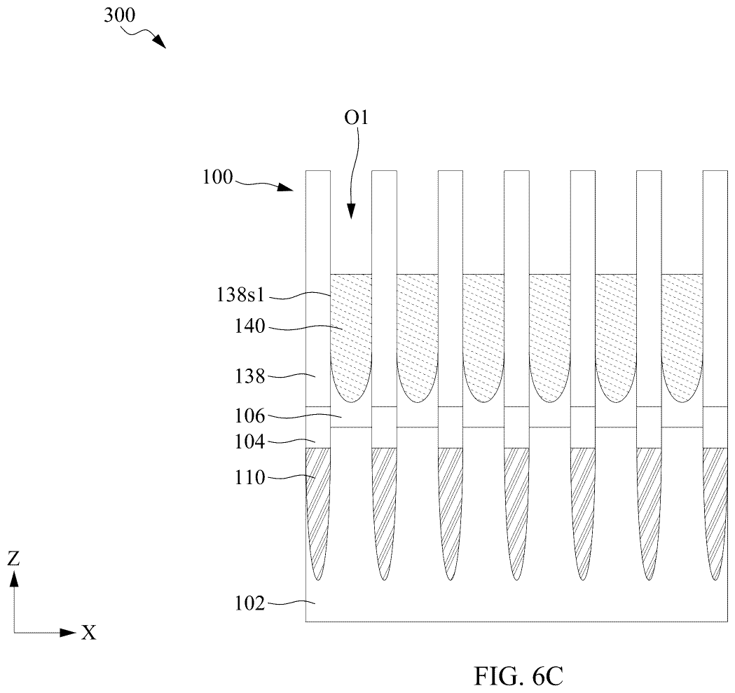

Referring to FIGS. 6A, 6B, and 6C, a portion 150p2, as shown in FIGS. 5A, 5B and 5C, of the isolation element 150 may be removed. The portion 150p2 may be disposed on the surface 138s1 of the spacer 138 and on the upper surface of the capacitor contact 140. A portion of the surface 138s1 of the spacer 138 may be exposed by the isolation element 150. The capacitor contact 140 may be exposed by the isolation element 150. The portion 150p2 of the isolation element 150 may be removed by an etching technique, such as a dry etching technique or other suitable techniques.

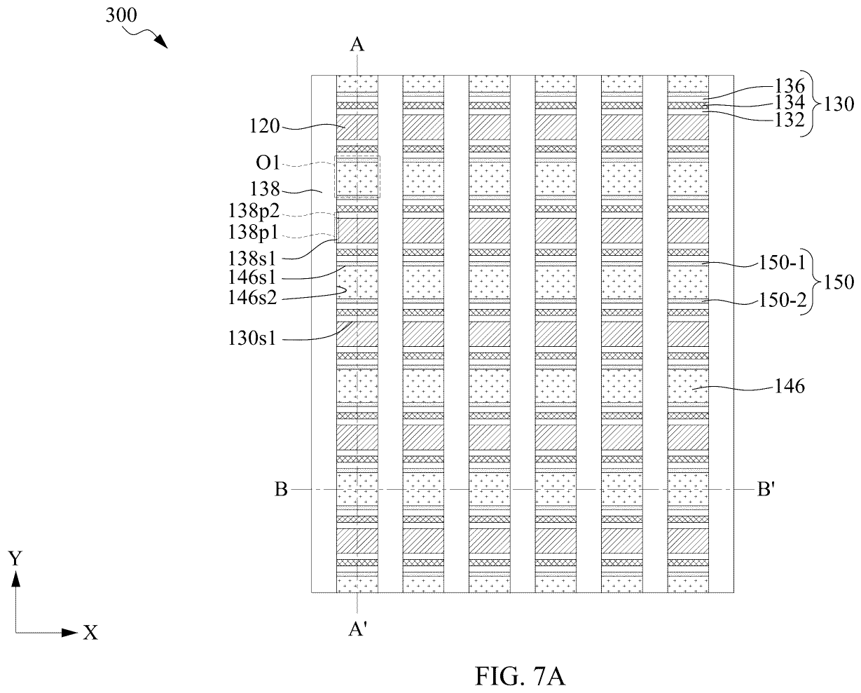

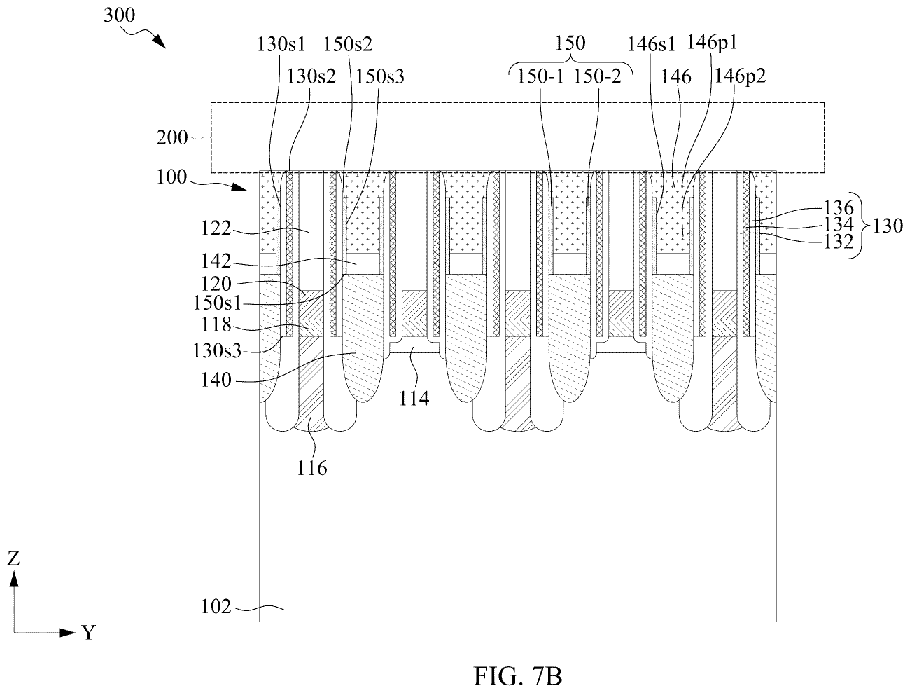

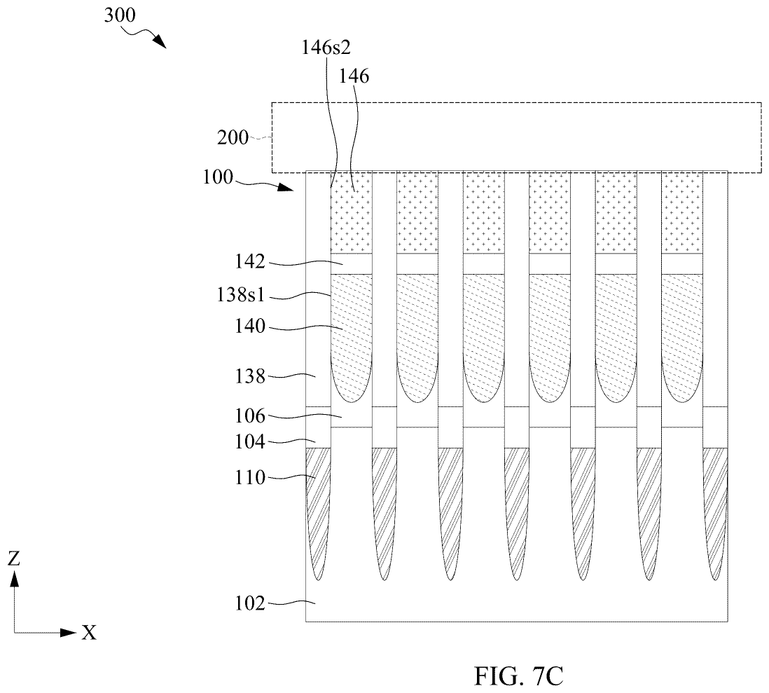

Referring to FIGS. 7A, 7B, and 7C, the pad 146 may be formed on the openings O1. The pad 146 may cover the isolation element 150. The pad 146 may be electrically connected to the capacitor contact 140. As a result, the carrier 100 may be produced. The pad 146 may be formed by, for example, ALD, CVD, PVD, FCVD, LPCVD, or other suitable processes. The device 200 may be formed on or over the carrier 100, thereby producing the semiconductor device 300.

One aspect of the present disclosure provides a semiconductor device. The semiconductor device includes a substrate, a first spacer, a second spacer, a third spacer, a fourth spacer, a capacitor contact, an isolation element and a landing pad. The first spacer and second spacer are over the substrate and extend along the first direction. The third spacer and fourth spacer are over the substrate and extend along a second direction different from the first direction. The capacitor contact is surrounded by the first spacer, the second spacer, the third spacer, and the fourth spacer. The isolation element is disposed on the capacitor contact. The isolation element extends along the first direction. The landing pad is disposed on the isolation element and electrically connected to the capacitor contact.

Another aspect of the present disclosure provides a semiconductor device. The semiconductor device includes a substrate, a first spacer, a second spacer, a capacitor contact, an isolation element and a landing pad. The first spacer and second spacer are over the substrate and extend along the first direction. The capacitor contact is disposed between the first spacer and the second spacer. The isolation element is disposed on the capacitor component. The landing pad is disposed on the capacitor contact. The landing pad includes a neck portion defined by the isolation element.

Another aspect of the present disclosure provides a method of manufacturing a semiconductor device. The method includes: providing a substrate; forming a first spacer and a second spacer over the substrate and extending along a first direction; forming a third spacer and a fourth spacer over the substrate and extending along a second direction different from the first direction, wherein the first spacer, the second spacer, the third spacer, and the fourth spacer define an opening; forming a capacitor contact within the opening; and forming an isolation element within the opening, wherein the isolation element extends along the first direction; and forming a landing pad on the isolation element and the capacitor contact.

The embodiments of the present disclosure illustrate a semiconductor device. The semiconductor device includes an isolation element over a capacitor contact. By incorporating the isolation element, the distance between a landing pad and a bit line can be increased, resulting in reduced leakage. In some embodiments, a portion of the isolation element is removed to allow a larger surface of the landing pad in contact with the capacitor contact, which reduces the resistance and enhance the performance of the semiconductor device.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate;
a first spacer and a second spacer over the substrate and extending along a first direction;
a third spacer and a fourth spacer over the substrate and extending along a second direction different from the first direction;
a capacitor contact surrounded by the first spacer, the second spacer, the third spacer, and the fourth spacer;
an isolation element disposed on the capacitor contact, wherein the isolation element extends along the first direction; and
a landing pad disposed on the isolation element and electrically connected to the capacitor contact.

2. The semiconductor device of claim 1, wherein a lateral surface of the third spacer is exposed by the isolation element is a top view.

3. The semiconductor device of claim 1, further comprising:
a bit line extending along the first direction and disposed between the third spacer and the fourth spacer.

4. The semiconductor device of claim 3, wherein the bit line is spaced apart from the isolation element.

5. The semiconductor device of claim 1, wherein a first distance between an upper surface of the first spacer and the substrate is different from a second distance between an upper surface of the isolation element and the substrate.

6. The semiconductor device of claim 5, wherein the first distance is greater than the second distance.

7. The semiconductor device of claim 5, wherein the landing pad covers the upper surface of the isolation element.

8. The semiconductor device of claim 1, wherein the landing pad has a first side facing the first spacer, and the first side of the landing pad is spaced apart from the first spacer by the isolation element.

9. The semiconductor device of claim 8, wherein the landing pad has a second side abutting the first side and facing the third spacer, and the second side is in contact with the third spacer.

10. The semiconductor device of claim 1, wherein the isolation element comprises silicon nitride, silicon oxynitride, or a combination thereof.

11. The semiconductor device of claim 1, wherein a first distance between a lower surface of the first spacer and the substrate is different from a second distance between a lower surface of the isolation element and the substrate.

12. The semiconductor device of claim 11, wherein the first distance is less than the second distance.
